(19) United States
(12) Patent Application Publication
(10) Pub. No.: US 2008/0129553 A1
(43) Pub. Date: Jun. 5, 2008

(54) Method for Configuring an Operating Unit of a Control and Control Device

(75) Inventors: Jurgen Rotzler, Steinen (DE); Thomas Grundmann, Rheinfelden (DE); Peter Heidecker, Steinen (DE)

Correspondence Address: GUDRUN E. HUCKETT DRAUDT, SCHUBERTSTR. 15A, WUPPERTAL, 42289, omitted

(73) Assignee: ROTZLER GMBH + CO. KG, Steinen (DE)

(21) Appl. No.: 11/950,602

(22) Filed: Dec. 5, 2007

(30) Foreign Application Priority Data
Dec. 5, 2006 (EP) 06 025 063.6

(51) Int. Cl. H04L 17/30; H03K 17/94

(52) U.S. Cl. 341/22; 341/175

(57) ABSTRACT

In a method for configuring at least one mobile operating unit of at least one control, wherein the at least one operating unit is detachably connectable to the at least one control, wherein the at least one operating unit has a display, a memory, and an input device, the configuration information, required for configuring the at least one operating unit, is transmitted from the at least one control to the at least one operating unit at the time of connecting the at least one operating unit to the at least one control. The configuration information is then utilized in the at least one operating unit. The configuration information saved in the memory can be overwritten by new configuration information received from the control.

### BACKGROUND OF THE INVENTION

The invention relates to a method for configuring at least one operating unit of at least one control, in particular, a microprocessor-based control in a bus system with variable assignment, wherein the operating unit is detachably connected to the control and wherein the operating unit has a display, a memory, and an input device.

The invention further relates to a control device, in particular, for a machine such as a conveying or lifting device or vehicle, wherein the control device comprises at least one microprocessor-based control in a bus system and at least one operating unit. The control is a machine control and the operating unit is connected to the control by means of a connecting cable or a wireless connection, wherein the connection of operating unit and control is detachable, wherein the operating unit has a housing and a display arranged in the housing. In the housing, a processor for operating the display is provided. An emergency power-off switch is provided at the head of the operating unit and the operating unit has a memory and an input device. In the memory, configuration information is stored; the memory has memory space for only one set of configuration information and the configuration information in the operating unit can be overwritten by the control.

Machines are generally operated by machine controls that process control commands input by an operator. Such machine controls are used, for example, in conveying or lifting technology, for example, in connection with cable winches, cranes or the like; other applications of such machine controls include, for example, their use in special vehicles such as tow trucks, garbage trucks, fire trucks, robot vehicles or the like. Modern machine controls comprise one or several integrated microprocessors on which, for controlling the machine, software applications are being run. Such so-called microprocessor-based controls are known, inter alia, by the term embedded systems.

An operating unit is to be provided that enables communication between the operator and the control; by means of the operating unit the operator can input inter alia control commands. With such an operating unit, for example, a winch or crane is controlled and lifting or lowering of a load is effected.

Depending on the type of microprocessor-based control, or the software application being run, of the machine or the vehicle to be controlled, by means of the operating unit different control commands are to be communicated. These different control commands can be actuated by different keys on the connected operating unit. Since the key assignment of an operating unit depends greatly on the provided software applications or the machine to be controlled, it is therefore necessary, depending on the type of application or the machine to be controlled, to provide different operating units. Therefore, a plurality of operating units must be provided by the manufacturer and must be stocked at the customer. This is expensive.

In the case of, for example, fire trucks or vehicles for military purposes, the are usually several controls by means of which different devices of the vehicle can be controlled. Each control has its own operating unit wherein each operating unit must be adapted specifically to the assigned control and therefore cannot be exchanged for an operating unit of a control of a different device. In order to ensure permanent readiness of the vehicle, for example, in the case of fire trucks, for each control a matching spare operating unit must be stored. This entails a high logistic as well as financial expenditure.

Depending on the geographic location of use, the display of the operating unit must be provided in different languages. In the past, this required that the designated language had to be assigned to the operating unit by the manufacturer. Only one language is then saved on the operating unit. It is also possible to provide several languages on the operating unit so that the desired language can be selected by the operator. This requires however a correspondingly large memory space and administrative expenditure in the operating unit.

It is desirable that an operating manual or an abbreviated manual and/or maintenance information can be displayed on the display of the operating unit.

Also, the display of diagnostic tools is desirable. This also requires memory space and administrative expenditure in the operating unit.

### SUMMARY OF THE INVENTION

It is an object of the present invention to provide a method for configuring an operating unit of a control, in particular, a microprocessor-based control that enables with a simple configuration of the operating unit a multitude of applications of the same operating unit.

It is another object of the present invention to provide a control device whose operating unit is of a simple configuration and can be utilized in various ways.

In accordance with the present invention, this is achieved in connection with the method in that, when connecting an operating unit to the control, all required configuration information for the operating unit is transferred from the control to the operating unit and is utilized in the operating unit.

In accordance with the present invention, this is furthermore achieved in connection with the control device in that the input device has keys with variable key assignment display.

In connection with the method, it is provided that when connecting an operating unit to the control all required configuration information for the operating unit is transmitted from the control to the operating unit. The transfer of information is realized in particular after switching on the control, in particular, after the initialization process. The control is in particular a microprocessor-based system (“embedded system”). Configuration information can be, for example, information in regard to the key assignment of the operating unit or language information. The configuration information however can also comprise a different type of information or additional information relating to the configuration of the operating unit at this control. In particular, the configuration information comprises information in order to make the operating unit ready for operation, information in regard to menu screens, information as regards the control logic, help text, operating information, safety tips, error messages, maintenance information, information regarding preventive maintenance, repair and servicing information, diagnostic tools, other interface definitions and interface functions and/or further information for the operator.

In that the configuration information is saved in the control and is transmitted from the control to the operating unit, the operating unit must not be provided with information in regard to the specific configuration. The operating unit can be “dumb”, i.e., it requires no own logic or configuration. In this way, it is simple to connect to the control an operating unit that is simple and versatile with regard to its use. The specific adaptation of the operating unit to the application in question is realized by means of the configuration information that is transmitted from the control onto the operating unit. The operating unit thus receives the required “intelligence” for the specific application only after it has been connected to the control. In this way, a simply configured operating unit can be used with different types of controls. An adaptation of the operating unit with regard to the application is realized only upon connection of the operating unit to the control so that it is not necessary to configure the operating unit prior to its use. For different controls, for example, several controls within one vehicle, the same operating unit of the same simple configuration without prior configuration can be utilized. In this way, in order to ensure a permanent readiness of several devices only one type of spare operating unit, in particular, only a single spare operating unit, must be available. This simplifies maintenance, stock-keeping, and logistics.

The method according to the invention can be used for a plurality of applications in which one or several operating units are to be configured for one or several controls, in particular, in a bus system with random assignment. When using a control device that comprises several controls and several operating units, it is provided that the transfer of the configuration information from one control to one or several correlated operating units is realized when the control is connected by means of the bus system to the operating units, for example, when switching on and initializing the control. In this case, it is in particular provided that a control, after the initialization process, i.e., after activation, searches the correlated operating units and transmits to these operating units the configuration information. The examples that are provided represent only a small selection of possible applications. The method according to the invention can be utilized in stationary as well as mobile machines, on land, on water or underwater, underground, in outer space, or in other areas.

Advantageously, the configuration information is saved in the memory of the operating unit. In this way, the transfer of information is required advantageously only upon first connection of the control to the operating unit. However, it can also be provided that the information is transferred each time a connection of the operating unit to the control takes place.

Advantageously, each time a connection of the operating unit to the control is realized, it is checked whether the configuration information saved within the operating unit is identical to the configuration information saved within the control. Should the information be different, it is provided that the configuration information of the control is transmitted to the operating unit and saved in the operating unit. When doing so, advantageously, the configuration information already present within the operating unit is overwritten so that the required memory space in the operating unit must be only large enough for one set of configuration information. When an operating unit that already contains the configuration information of a first control is connected to a second control, automatically the configuration information saved within the operating unit is overwritten with the configuration information of the second control. In this way, one and the same operating unit can work when connected to a first control, for example, with a first language and a first key assignment, and, when connected to a second control, can work with a second language and/or a different key assignment that is stored within the second control. In this way, a simple exchange of the operating units is possible.

Advantageously, the input device comprises at least one key wherein the input device is particularly a plastic film keyboard or keypad. The configuration information comprises advantageously information with regard to the key assignment of at least one key wherein the operating unit displays the key assignment information. The information in regard to the key assignment can indicate which functions one or several keys have. In this way, an assignment of functions to the individual keys is enabled for the operator. However, it can also be provided that the configuration information includes an identifier that characterizes the key assignment. In this way, it is possible for the operator to apply an appropriate labeling of the keys, for example, by applying pre-manufactured labeling stickers or strips. Thus, in a simple way an adaptation of the operating unit to the respective application and configuration of the control can be provided. The information required for the adaptation will be provided to the operator by the control and by means of the display on the operating unit.

The key assignment information is displayed in particular on the display. It can also be provided that the key assignment information is displayed on the key itself or adjacent to the key, for example, by means of a diode or the like. For displaying the key assignment information the key can also have a variable symbol display and/or labeling display or it can have a variable symbol display and/or labeling display adjacent to the key. The display of the key assignment information can also be realized at a different area of the operating unit wherein the display is such that the key assignment information can be easily correlated to one or several keys.

The term key is to be understood in the broadest sense. The key can be, for example, an individual push button, a joystick or a touch key. It can also be provided that the key is displayed on a display, for example, on an LCD display and can be actuated by means of a pen or by means of one or several touch keys. Other keys can also be employed, for example, a touch screen.

It is provided that the configuration information includes language information of the language that is selected in the control as the standard language or default language. The language information comprises not only the indication which language is selected but also the entire language information, i.e., the terminology and sentences to be displayed by the operating unit. When connecting the operating unit for the first time to the control, first the standard language (default language) is loaded onto the operating unit. It is provided that when the operator selects at the operating unit a language that is different from the default language, the language information of the selected language is transferred from the control to the operating unit and the language information that is presently stored within the operating unit is overwritten by the language information of the selected language.

For loading the default language it is provided that first the language saved within the operating unit is queried when the control is switched on and initialized. Should the language saved within the operating unit upon first connection to the control differ from the default language of the control, it is provided that the standard or default language is transmitted to the operating unit and saved thereon. It can also be provided that the default language, when first connecting the operating unit to the control, is transmitted and saved on the operating unit without checking the language that is already stored on the operating unit. The operating unit is advantageously configured such that the language loaded on the operating unit is retained even when the operating unit or the control is switched off. Advantageously, the language that has been loaded onto the operating unit will be retained upon switching off the operating unit and also retained when the control is switched on again, in particular, when the language loaded on the operating unit deviates from the default language of the control. This is a function that can be selected by the operator. It can also be provided that the language saved in the operating unit when switching off the operating unit is retained within the operating unit only as long as the control itself is not switched off. When switching off the control, it can be provided that the language loaded on the operating unit is deleted. Expediently, switching on and off the operating unit has no effect on the language that is loaded on the operating unit. Advantageously, the additional configuration information is loaded again when starting the control or after connecting the operating unit to the control.

Should the operator desire a different language, the operator can enter a request into the operating unit. The entire language information is then overwritten by the language information of the selected language so that the operating unit has saved thereon only the language information of a single language. In this way, the required memory space can be kept minimal. At the same time, this provides a high operating comfort because the operator can select a desired language. When the operating unit is connected to a different control with a different default language, in particular when switching on the control, the default language of this control is transmitted automatically to the operating unit and saved thereon. When connecting an operating unit to a control and switching on the control, the default language of the control is therefore always loaded onto the operating unit, independent of which language the operating unit was loaded with beforehand.

Advantageously, the configuration information comprises an operating manual, servicing messages and/or information with regard to diagnostics. The operating manual can be an abbreviated version. The information for diagnostics is in particular information that is required for utilizing diagnostic tools. In this way, the information for operation, maintenance and/or diagnostics required for each application, respectively, can be displayed by the operating unit. Since the information is transmitted by the control, the operating unit itself must not have any such information loaded on it. Since different information in regard to operation, diagnostics and maintenance is required for different applications and the respective information is stored within the control and transmitted to the operating unit when connected, the memory space required in the operating unit itself is small and the administrative expenditure for administering data in the operating unit is minimal.

It is provided that the operating unit is connected by a connecting cable to the control and that the operating unit is supplied with electric energy by means of the connecting cable. In this way, only a connecting cable is required through which the information as well as the energy for operating the operating unit is transmitted. However, I can also be provided that the operating unit is connected wireless to the control. It is then possible to employ batteries as an energy supply of the operating unit.

In particular, the operating unit is connected to the control by means of a bus system, in particular CAN (controller area network) bus. When connecting the operating unit to the control by means of the connecting cable, it is provided that the control and the operating unit are connected to one another by a CAN bus. In case of a wireless connection between control and operating unit, control and operating unit each have a sending/receiving component (transceiver). The operating unit is connected to the mobile transceiver belonging to the operating unit particularly by means of a CAN bus system. The control is also connected to the stationary transceiver belonging to the control by means of a CAN bus system. In both cases, however a different type of bus system, in particular, a field bus system, can be provided. The connection between the mobile transceiver of the operating unit and the stationary transceiver of the control is realized advantageously by means of a special radio-suitable bus system that is different from the bus system of the control. When the operating unit is supplied with electric energy from a battery, the battery takes over not only the energy supply of the operating unit but also the energy supply of the mobile transceiver.

For a control device that comprises a control and an operating unit detachably connectable to the control, wherein the operating unit has a display, a memory, and an input device, it is provided that the input device has keys with variable key assignment display.

The key assignment display can be labeling as well as a display of the key assignment, for example, in the form of a diode or a variable symbol and/or labeling display. The variable key assignment display enables an adaptation of the display of the key assignment to the respective control.

Advantageously, the input device is a plastic film keyboard or keypad wherein at least one key of the keyboard has at least one pocket for receiving a labeling strip. The pocket for receiving the labeling strip enables in a simple way an adaptation of the key labeling. Therefore, a variable utilization of the operating unit is possible in a simple way. For the different types of controls only one operating unit must be provided by the manufacturer and can be supplied with different labeling strips for different applications. When connecting the operating unit to a control, the key assignment information is transmitted to the operating unit and displayed thereon so that the operator can select the labeling strip that shows the key assignment and can apply it to the operating unit.

Advantageously, one pocket is arranged between at least one switching element and a cover film of the film keyboard. The labeling strip can be arranged in the pocket. The pocket protects the labeling strip from the environment, i.e., soiling or splash water. In the pocket, the labeling strip can be arranged in a simple way. When embodying the labeling strip from plastic material, light can pass through the labeling strip so that the keyboard illumination remains visible. In order to enable a simple insertion and exchange of the labeling strips, it is provided that special strips are provided as an insertion aid; such aids are in particular arranged in the respective pockets when manufacturing the operating unit. The strips that serve as insertion aids are advantageously more narrow and longer than the pockets and sized such that they can be placed together with the labeling strip in a pocket. The strip serving as an insertion aid can be pulled out easily from the pocket. Advantageously, on the strip that serves as an insertion aid an initial assignment of keys, for example, a key for switching on and off as well as a help key, are indicated.

### BRIEF DESCRIPTION OF THE DRAWING

FIG. 1 shows a cable winch with a control device in a schematic illustration.

FIG. 2 is a schematic section view of a film keypad of the operating unit of the control device of FIG. 1.

FIG. 3 shows embodiments of labeling strips for the operating unit of FIG. 1.

FIG. 4 is a schematic illustration of one embodiment of a control device.

FIG. 5 is a schematic illustration of a control device that comprises several controls and several operating units.

FIG. 6 is a schematic plan view of a film keyboard with labeling strips.

### DESCRIPTION OF THE PREFERRED EMBODIMENTS

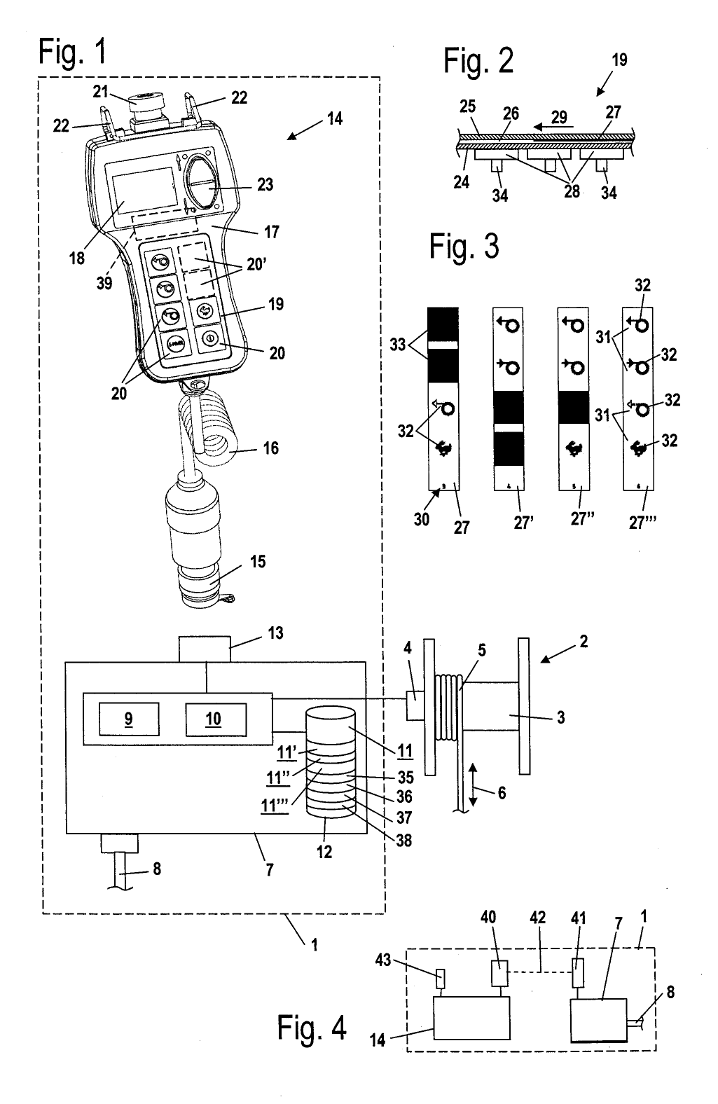

FIG. 1 illustrates a specific embodiment of a general type of control device with a control that is in particular microprocessor-based and with an operating unit for a conveying or lifting device in the form of a schematically shown cable winch 2. The conveying or lifting device can also be a different type of device, in particular any kind of gypsy winch, a crane or the like. Such a general control device with a control and an operating unit can also be used in other devices, for example, devices on a vehicle such as a tow truck, a garbage truck, a fire truck, a robot vehicle or a vehicle for military purposes. On such vehicles, the control device, for example, can control cable winches, lifting devices, a fire truck ladder or motor ladder or the like. Generally, the method according to the invention and the control device can be utilized in connection with all machine controls, whether on land, underground, on or under water, in the air, in outer space or other places. Even though the invention will be explained in connection with one control and one operating unit, the method is designed for configuring one or several operating units with one or several controls in one or several control devices.

The control device illustrated as an example is comprised of at least one control with at least one operating unit and serves for operating a cable winch 2 with a cable drum 3, driven in rotation by drive motor 4. A cable 5 is wound about the cable drum 3. Depending on the rotational direction of the drive motor 4, the cable 5 is wound onto the cable drum 3 or unwound from the cable drum 3. This is indicated by the double arrow 6. For controlling the drive motor 4, the cable winch 2 has a control device 1. The control device 1 can control the drive motor 4, for example, in an indirect way by actuators such as valves or the like. The control device 1 comprises a control 7 as well as an operating unit 14 connected to the control 7. For this purpose, the control 7 has a connecting socket 13 into which a connecting plug 15 of the operating unit 14 can be inserted. The operating unit 14 is a mobile and portable, particularly hand-held, operating unit. The operating unit 14 can be carried, for example, by means of a belt or the like, across the shoulder of the operator. It can be expedient to mount the operating unit 14 stationarily and in particular at a fixed location.

The control 7 has a connecting line 8 for current supply. The current supply of the operating unit 14 is realized by a control 7 and a connecting cable 16 with which the operating unit 14 is connected by connecting plug 15 to the connecting socket 13 of the control 7. The control 7 is advantageously configured as an “embedded system” and has a processor 9 with a main memory 10. The control 7 has moreover a memory 12. In the control 7 several software applications 11, 11′, 11″, 11′″ are saved. The software applications 11 can be saved within the memory 12. By means of the software applications 11, 11′, 11″, 11′″, the functions of the cable winch 2 such as lifting the cable or lowering the cable or fast movement can be controlled, governed and monitored. The number and type of software applications 11 can be different, depending on the application. In this connection, it is provided that all possible software applications 11 are saved in the control 7. The activation of the software applications 11 required for a respective use is realized by means of configuration parameters. In this connection, an adaptation and adjustment of the individual software applications 11 to the respective use can be carried out.

The memory 12 has a memory space 35 in which the configurations of the software applications 11, i.e., the configuration parameters, as well as the default language of the operating unit 14 are saved. The memory 12 has a further memory space 36 in which the key assignment of the operating unit 14 is saved. In a further memory space 37 the language information for all selectable languages of the operating unit 14, including the default language, are saved. A manual or an abbreviated manual, maintenance information and/or diagnostic tools are saved within a further memory location 38.

In the memory 12 further configuration information can be saved. Configuration information may include, for example, information in order to make the operating unit ready for use, information in regards to menu screens, information in regard to the logic of the control, information text, operating instructions, safety tips, error messages, information in regard to preventive maintenance, information regarding servicing and repair, other interface definitions and interface functions and/or further information for the user. Other and/or additional configuration information can be provided also.

The operating unit 14 has a housing 17 in which a schematically illustrated memory 39 is arranged. A display 18 is arranged on the housing 17 and is, for example, an LCD display. In the housing 17 a processor (also not illustrated in FIG. 1) for operating the display 18 is provided. Adjacent to the display 18, there is a rocker switch 23 that functions as a joystick and with which the movement of the cable 5 can be activated (cable on; cable off). For operating the cable winch 2 the operating unit 14 has a film keypad 19 with several keys 20. The keys 20 have assigned different functions that can be activated by the operator by actuation of the corresponding keys 20. Upon activation of the corresponding key 20, the selected function starts one or several software applications 11 that run automatically. For example, one key 20 can be provided for selecting a gear and another key 20 for automatic feeding of the cable 5, in particular, in case of operation of the winch by a single operator. The control 7 can comprise a variety of software applications 11. Depending on the special need, the applications 11 for performing the function that is assigned to a key 20 are automatically activated. The keypad 19 has eight keys arranged in two rows wherein two keys 20′ in the embodiment do not have a function assigned. The number of assigned and unassigned keys can vary depending on the use. At the head of the operating unit 14 there is an emergency shut-off switch 21. On either side of the emergency shut-off switch 21 there are protective brackets 22 that provide a mechanical protection from damage of the emergency shut-off switch 21 and prevent that the operating unit 14 can be put down on the surface of the display 18.

Instead of keys 20 that are formed on the film keyboard 19 other keys such as, for example, push buttons, joysticks, touch keys or keys that are displayed on a display, in particular, an LCD display or touch screen, are provided and can be activated by means of touch keys or by means of a pen. The display can be the display 18 but it can also be a separate display for the keys.

In the operating unit 14 there is initially, i.e., after completion of manufacture of the operating unit 14, no configuration information saved such as information in regard to the key assignment and language information. This information is saved in the control 7. Upon first connection of the operating unit 14 to the control 7 by means of connecting cable 16 the operating unit 14 is connected to a bus system, in particular, a CAN bus system of the control 7. By means of connecting cable 16 the operating unit 14 is also supplied with electric energy. By means of the bus system the operating unit 14 is supplied with information in regard to the key assignment as well as language information of the default language. Moreover, an operating manual or an abbreviated operating manual, maintenance information and/or diagnostics information can be transmitted. The transmission is realized in particular after switching on and initializing the control 7. It can also be provided that this information is transmitted only when requested by the operator. Also, further configuration information can be transmitted upon first connection or upon request by the operator. This information is saved within the memory 39 of the operating unit 14. The memory 39 of the operating unit 14 is designed such that memory space for only one set of configuration information, including language, is available. A memory with comparatively minimal memory space can be utilized as memory 39.

The information in regard to key assignment can be displayed on the display 18. For this purpose it can be provided that the operator switches on the display 18 and must push a predetermined key, for example, a help keep. The information in regard to the key assignment can however also be displayed automatically, and independent of input by the operator, on the display 18.

The display of information in regard to the key assignment can also be realized at the keys 20 themselves or adjacent to the keys 20. The display can also be realized on a different area of the operating unit in such a way that the key assignment information can be correlated easily to one key or several keys. The display can be realized, for example, by means of diodes or the like. It is also possible to provide keys with variable symbol and/or labeling display wherein the key assignment information is realized at the display of the key or a variable symbol and/or labeling display is arranged adjacent to one or several keys. The transfer of the configuration information from the control 7 to the operating unit 14 is advantageously realized only upon initialization of the control 7. When the operating unit 14 is switched off or the connection between operating unit 14 and control 7 is separated, generally no new transfer of the configuration information takes place when switching on the operating unit 14 again. In this way it is prevented that a language selected by the operator is overwritten each time the operating unit 14 is switched off and on again. The operating unit can also be configured such that the language last used by the operator will be retained even when the operating unit or the control is switched off. Advantageously, the further configuration adjustments are loaded again when starting the control or after connecting the operating unit to the control.

The configuration of the film keypad 19 is schematically illustrated in FIG. 2. The film keypad has in the an area of each key 20 a switching element 28 that makes electric contact upon pushing on the correlated key 20. Underneath each one of the switching elements 28 there is advantageously a light-emitting diode 34 that illuminates the keys 20. The switching elements 28 are covered by a protective film 24 that seal-tightly closes off the housing 17 in the area of the film keypad 19. Above the protective film 24 there is a cover film 25 resting on the protective film 24. Between the films 24 and 25 there is at least one pocket 26 into which a labeling strip 27 can be inserted in the direction of the arrow 29 shown in FIG. 2. In the illustrated embodiment two pockets 26 are provided that extend each across a row of four keys 20.

In FIG. 3 an embodiment of labeling strips 27, 27′, 27″, 27′″ is shown. Each labeling strip 27, 27′, 27″, 27′″ has four transparent display fields 31 that are to be positioned in the area of the keys 20. Depending on the provided key assignment, the display fields 31 have symbols 32 that, for example, represent the automatic feeding of the cable 5 and rapid feed. In the area of keys 20 without assignment there are blackened fields 33. The blackening of the fields 33 is done such that the light of the light-emitting diodes 34 is shielded and the fields 33 remain dark. The keys 20 without assignment therefore appear black. At one end the labeling strips 27, 27′, 27″, 27′″ each have an identifier 30. The identifier 30 is comprised in the shown embodiment of a numeral. However, other types of identifiers 30 can be provided.

On the display 18, the identification of the labeling strips 27, 27′, 27″, 27′″ is shown; on their display fields 31 the actual key assignment of the film keypad 19 is illustrated. The operator can then select the labeling strips 27 with the appropriate identification 30 and insert them into the two pockets 26. For this purpose, in the pockets 26 an auxiliary strip 45, 45′, supplied by the manufacturer, can be arranged that is more narrow and longer than the labeling strips 27 (FIG. 6). This facilitates insertion of the labeling strips 27. The auxiliary strips 45,45′ can provide information in regard to which keys to push for first use (initial operation) of the keypad. This is indicated in FIG. 6 by the symbols 46, 48, and 49. In this way, the first use is simplified. By saving the configuration information in the control 7 and transferring it to the operating unit 14, the operating unit 14 can be matched in a simple way to the control 7. For this purpose, the operator must only insert the labeling strips 27 with the appropriate identifier that is indicated by the display 18 and insert them into the corresponding pockets 26.

Instead of a connecting cable 16, a wireless transmission of data between the operating unit 14 and the control 7 can be provided. For a wireless connection advantageously all types of radio signals, in particular short distance radio signals (for example, Bluetooth standard) can be utilized. Other types of wireless data transmission can be advantageous in this connection. The operating unit 14 can have a separate cable for energy supply when an additional external voltage supply is present.

Advantageously, the operating unit 14 is battery-operated. This is schematically shown in FIG. 4. The control 7 of the control device 1 shown in FIG. 4 has a transceiver 41, i.e., a component for wireless sending and receiving of data. The operating unit 14 has a transceiver 40. The transceivers 40 and 41 can be connected by a wireless connection 42 with one another. The connection of the transceiver 40 with the operating unit 14 and the connection of the transceiver 41 to the control 7 are realized advantageously by means of a CAN bus. The wireless connection 42 is realized by means of a wireless connection of suitable bus systems. For energy supply the operating unit 14 has a battery 43 that supplies the display 18 (FIG. 1) as well as the transceiver 40 with energy. Further devices of the operating unit 14 can also be supplied with energy by means of the battery 43. The control 7 has a connecting line 8 for energy supply. The battery 43 and the transceiver 40 are arranged outside of the operating unit 14 and are connected by a cable to the operating unit 14. The transceiver 41 is also arranged outside of the control 7 and connected to it by a cable. Advantageously, connectors are used for the transceivers 40, 41 that serve for connecting the operating unit 14 to the control 7 by means of a cable. The transceivers 40, 41 and the battery 43 however can be integrated in the operating unit 14 or the control 7, respectively. The configuration of the control device 1 matches in other respects that of the control device 1 shown in FIG. 1.

When the operating unit 14 is connected to a control 7, the control 7 checks whether the configuration information of the operating unit 14 coincides with the permissible configuration information saved in the control 7. When a match is not confirmed, the configuration information is transmitted from the control 7 to the operating unit 14 and saved therein. The memory 39 of the operating unit is overwritten in this case; this means that the operating unit 14 requires only minimal memory space. In this connection, it can be provided that the language that is saved in the operating unit 14, particularly a language that has been selected by an operator, is retained and not overwritten by the default language of the control 7. It can also be provided that the configuration information is transmitted each time the operating unit is connected to the control and is then saved in the operating unit without prior checking of the already saved configuration information.

When the operating unit 14 is connected to the control 7 the operator can change the pre-selected language. The language that is selected by the operator is then transmitted from the control 7 to the operating unit 14 and is saved in the memory 39. In this connection, the default language that has been saved in the operating unit 14 is overwritten.

The operator can request by means of the operating unit 14 from the control 7 also an operating manual or an abbreviated manual. This manual is then transmitted, when requested by the operator, to the operating unit 14 and is cached therein. Advantageously, no permanent storage of the operating manual in the operating unit 14 takes place because this would require additional memory space. Because only the information that is momentarily required is saved in the operating unit 14, the memory capacity provided in the operating unit 14 can be small. In the same way, the operator can request maintenance information and/or diagnostic tools from the control 7. Also, additional and/or other configuration information can be transmitted to the operating unit 14 as requested by the operator or upon switching on the control 7.

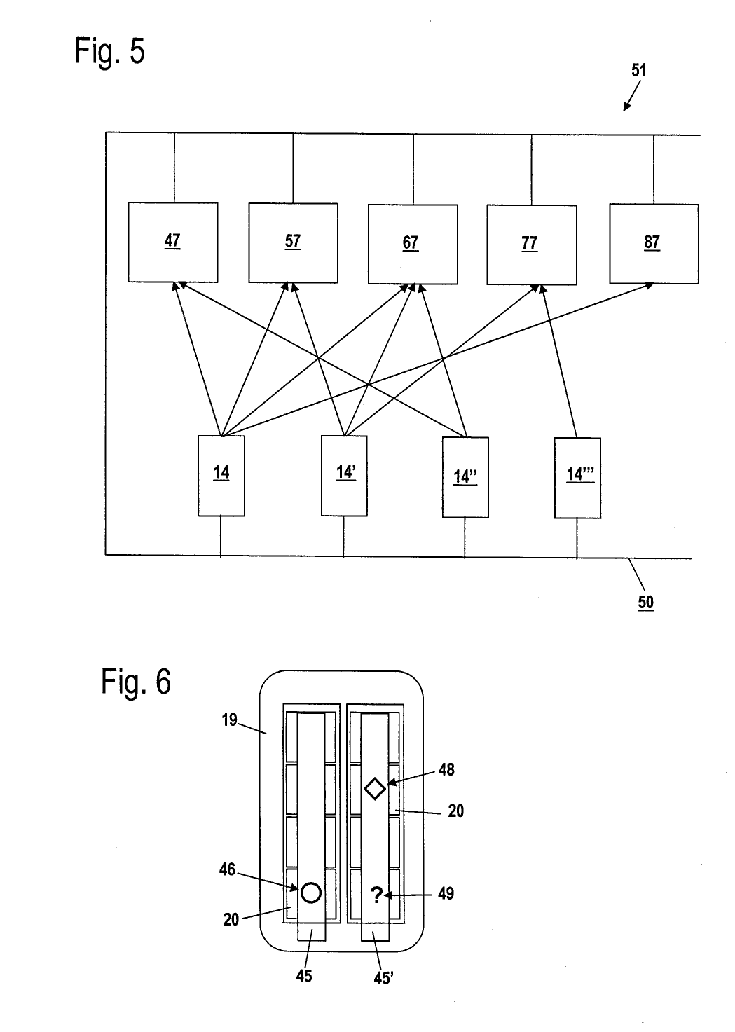

Advantageously, several controls and/or several operating units are operated in a common bus system, in particular, a CAN bus system. This is schematically shown in the embodiment of FIG. 5. FIG. 5 shows a control device 51 that comprises five controls 47, 57, 67, 77, 87 as well as four operating units 14, 14′, 14″, 14′″. The four operating units 14, 14′, 14″, 14′″ are advantageously identically configured. However, the operating units 14, 14′, 14″, 14′″ can also be different. In this connection, the operating units 14, 14′, 14″, 14′″ can be different particularly in regard to the type and number of input devices, for example, push buttons, switches, rocker switches, etc. The type and number of input devices of each operating unit 14, 14′, 14″, 14′″ is selected such that all desired or maximally possible functions of the control or the controls with which this operating unit 14, 14′, 14″, 14′″ interacts or is able to interact can be actuated by the input devices. The five controls 47, 57, 67, 77, 87 can be different controls. For example, the control 47 can be the control of a winch, the control 57 can be the control of a crane, the control 67 can be the control of a lift gate, the control 77 can be the control of a wrecker device, and the control 87 can be the control of a dozer blade. The list is to be understood as an exemplary list only. For example, controls of other devices or a different number of controls can be connected to one another within the bus system. In the control device 51, i.e., in the controls 47, 57, 67, 77, 87 and the operating units 14, 14′, 14″, 14′″, it is predetermined which operating unit 14, 14′, 14″, 14′″ should act on which control 47, 57, 67, 77, 87. This information can be stored within the bus system 50. In the illustrated embodiment it is provided that the operating unit 14 can act on the controls 47, 57, 67, 87, the operating unit 14′ can act on the control 57, 67, 77, the operating unit 14″ can act on the controls 47, 67, and the operating unit 14′″ can act on the control 77. In this connection, several operating units 14, 14′, 14″, 14′″ can act on a control 47, 57, 67, 77. However, it must be ensured that at any time only one of the operating units 14, 14′, 14″, 14′″ can act on one of the controls 47, 57, 67, 77, 87. For this purpose, it can be provided that the operating unit 14, 14′, 14″, 14′″ that selects first one of the controls 47, 57, 67, 77, 87 has priority and is connected to the selected control. Later access of another operating unit 14, 14′, 14″, 14″ to the selected control 47, 57, 67, 77, 87 is then prohibited.

It can be provided that an operating unit 14, 14′, 14″, 14′″ acts simultaneously on several controls 47, 57, 67, 77, 87. For this purpose, the input device must have corresponding operating elements such as push buttons, joysticks and the like. The configuration must enable such activation.

For operating several controls 47, 57, 67, 77, 87 on a common bus system 50, it is provided that upon activation of a control 47, 57, 67, 77, 87 on the bus system 50, for example, by switching on the control, a control 47, 57, 67, 77, 87 will search for the assigned operating unit 14, 14′, 14″, 14′″ and will configure it by transmitting the appropriate configuration information.

In addition to the bus system 50, the controls 47, 57, 67, 77, 87 as well as the operating units 14, 14′, 14″, 14′″ can also be connected by supply lines, lines for emergency shut-off as well as an emergency actuation. Also additional or other connections of the controls and of the operating units relative to one another can be expedient.

When operating several controls 47, 57, 67, 77, 87 in a network, it is possible to configure all controls 47, 57, 67, 77, 87 by means of a central computer. The configuration of the controls 47, 57, 67, 77, 87 can also be realized by means of the Internet. The configuration, in particular, the configuration by means of the Internet, can be done e.g. in connection with an update function that is carried out automatically or upon request by the operator. Since the configuration information is transmitted by the controls 47, 57, 67, 77, 87 to the operating units 14, 14′, 14″, 14′″, a separate configuration of the operating unit 14 is not required. Accordingly, the configurational expenditure is reduced.

The specification incorporates by reference the entire disclosure of European priority document 06 025 063.6 having a filing date of Dec. 5, 2006.

While specific embodiments of the invention have been shown and described in detail to illustrate the inventive principles, it will be understood that the invention may be embodied otherwise without departing from such principles.

What is claimed is:

1. A method for configuring at least one mobile operating unit of at least one control, wherein the at least one operating unit is detachably connectable to the at least one control, wherein the at least one operating unit comprises a display, a memory, and an input device, the method comprising the steps of:
transmitting configuration information, required for configuring the at least one operating unit, from the at least one control to the at least one operating unit at the time of connecting the at least one operating unit to the at least one control and utilizing the configuration information in the at least one operating unit.

2. The method according to claim 1, wherein the step of transmitting is carried out when the at least one operating unit is connected to the at least one control for the first time.

3. The method according to claim 1 further comprising the step of saving the configuration information in the memory of the at least one operating unit.

4. The method according to claim 1, further comprising the steps of checking each time the at least one operating unit is connected to the at least one control whether configuration information saved in the memory of the at least one operating unit matches configuration information of the at least one control and, in case the configuration information of the at least one operating unit does not match the configuration information of the at least one control, initiating said step of transmitting and overwriting the configuration information saved in the memory of the at least one operating unit with the configuration information of the at least one control being transmitted in said step of transmitting.

5. The method according to claim 1, wherein the input device comprises at least one key and wherein the configuration information comprises information in regard to a key assignment of the at least one key, wherein the at least one operating unit displays the key assignment.

6. The method according to claim 1, wherein the configuration information comprises language information of a default language of the at least one control.

7. The method according to claim 6, wherein, upon selection at the at least one operating unit of a second language that is different from the default language, language information of the second language is transmitted from the at least one control to the at least one operating unit and wherein language information saved in the memory of the at least one operating unit is overwritten by the language information of the second language being transmitted.

8. The method according to claim 1, wherein the configuration information comprises at least one of an operating manual, maintenance information, and diagnostic information.

9. The method according to claim 1, further comprising the steps of connecting the at least one operating unit to the at least one control by a connecting cable and supplying electric energy through the connecting cable to the at least one operating unit.

10. The method according to claim 1, further comprising the step of connecting the at least one operating unit to the at least one control by a wireless connection.

11. The method according to claim 1, further comprising the step of connecting the at least one operating unit to the at least one control by a bus system.

12. A control device comprising at least one microprocessor-based machine control in a bus system and at least one operating unit, wherein the at least one operating unit is detachably connectable to the at least one control by a connecting cable or a wireless connection, wherein the at least one operating unit comprises a housing provided with a display and a processor for operating the display, wherein the at least one operating unit further comprises an emergency shut-off switch, a memory, and an input device, wherein configuration information is saved in the memory and the memory is provided with memory space for only one set of configuration information and wherein the at least one control is able to overwrite the configuration information in the memory, wherein the input device has keys with a variable key assignment display.

13. The control device according to claim 12, wherein the input device is a keypad with keys and wherein at least one of the keys has at least one pocket arranged thereat for receiving a labeling strip.

14. The control device according to claim 13, wherein the keypad has a cover film and wherein the at least one pocket is arranged between at least one switching element of the at least one key and the cover film.

15. The control device according to claim 13, wherein the keypad has a switching element for each one of the keys and wherein electric contact is made when pushing on the switching element.

16. The control device according to claim 15, wherein the keypad has a light-emitting diode arranged underneath each one of the switching elements.

17. The control device according to claim 13, wherein an auxiliary strip is initially arranged in the at least one pocket and the auxiliary strip is longer and more narrow than the labeling strip to be inserted, wherein the auxiliary strip displays information in regard to which keys to push for initial operation of the at least one operating unit.

18. The control device according to claim 12, comprising several of said at least one machine control and several of said at least one operating unit.

19. The control device according to claim 18, wherein in the control device an assignment is provided which one of said several operating units acts on which one of said several controls.

20. The control device according to claim 12, wherein said bus system is a common bus system for operating said at least one machine control and said at least one operating unit.

21. The control device according to claim 19, wherein said bus system is a CAN bus.
